(19) United States
(12) Patent Application Publication
(10) Pub. No.: US 2016/0251750 A1
(43) Pub. Date: Sep. 1, 2016

(54) An evaporating crucible and an evaporating device

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventor: Jinzhong ZHANG, Beijing (CN)

(73) Assignees: Boe Technology Group Co., Ltd., Beijing (CN); Ordos Yuansheng Optoelectronics Co., Ltd., Inner Mongolia (CN)

(21) Appl. No.: 14/762,109

(22) PCT Filed: Jan. 20, 2015
(86) PCT No.: PCT/CN2015/071101

§ 371 Date: Jul. 20, 2015

(30) Foreign Application Priority Data
Sep. 1, 2014 (CN) 201410440677.7

(51) Int. Cl. C23C 14/24

(52) U.S. Cl. CPC C23C 14/243

(57) ABSTRACT

There are provided an evaporating crucible and an evaporating device in the invention. The evaporating crucible includes a crucible body in which a containing chamber is formed. The evaporating crucible further includes a heat-conductive layer, which is provided on an inner wall of the crucible body to surround the containing chamber and which is made of materials having higher thermal conductivity than the crucible body. The evaporating crucible provided in the invention is able to uniformly heat the evaporation materials and to improve the effect of the evaporation.

### FIELD OF THE INVENTION

The present invention relates to the field of manufacturing technologies of display device, and in particular, to an evaporating crucible and an evaporating device having the same.

### BACKGROUND OF THE INVENTION

For the realization of displaying by Organic Light-Emitting Diode (OLED), the use of a Low Temperature Poly-silicon (LTPS) panel with a Fine Metal Mask (FMM) has been in early mature stage.

In the use of the LTPS with the FMM, organic materials are applied to a rear panel of LTPS by the evaporation, and then red, green and blue elements are formed by patterns on the FMM. The evaporation is implemented in a vacuum chamber by a linear crucible. FIG. 1 is a structural schematic diagram of an existing evaporating crucible. In prior art, a crucible body 10 of the evaporating crucible is formed of titanium (Ti), which results in decreased temperature uniformity of the heated evaporating crucible, such that evaporation materials have a low heating uniformity; at this time, the inside of the evaporation materials is heated slowly due to a distance away from an inner wall of the evaporating crucible, while the outside of the evaporation materials which comes into a direct contact with the inner wall is heated quickly, such that a portion of materials have not been evaporated while another portion of materials are denatured due to overheat. This may lead to a waste of materials and may influence an effect of the evaporation.

### SUMMARY OF THE INVENTION

An objective of the invention is to provide an evaporating crucible and an evaporating device which allow evaporation materials to be more uniformly heated in an evaporation process.

To achieve above objective, the invention provides an evaporating crucible, including a crucible body in which a containing chamber is formed. The evaporating crucible further includes a heat-conductive layer which is provided on an inner wall of the crucible body to surround the containing chamber and which is made of materials having higher thermal conductivity than the crucible body.

Preferably, the materials of which the crucible body is made include titanium or titanium alloy, and the materials of which the heat-conductive layer is made include any one or more of copper, copper alloy, silver and silver alloy.

Preferably, the evaporating crucible further includes a heat-conductive structure which is arranged within the containing chamber and connected to the heat-conductive layer. When the evaporation materials are placed within the containing chamber, the evaporation materials are brought into contact with at least a portion of the heat-conductive structure, and when the evaporating crucible is being heated, the heat-conductive structure has no interference with the escape of the evaporation materials from an open side of the containing chamber.

Preferably, the heat-conductive structure includes a plurality of heat-conductive partition plates which divide the containing chamber into a plurality of sub-chambers with openings formed.

Preferably, the plurality of the heat-conductive partition plates include at least a first partition plate which is extended in a length direction of the containing chamber, and/or the plurality of the heat-conductive partition plates include at least a second partition plate which is extended in a width direction of the containing chamber.

Preferably, the plurality of the heat-conductive partition plates include a plurality of the first partition plates and a plurality of the second partition plates.

Preferably, the heat-conductive structure includes at least a heat-conductive web which divides the containing chamber into a plurality of sub-chambers in a depth direction of the containing chamber.

Preferably, the heat-conductive structure includes a plurality of heat-conductive webs which are arranged in the depth direction of the containing chamber.

Preferably, the heat-conductive structure is made of the same materials as the heat-conductive layer.

Accordingly, the invention also provides an evaporating device which includes the evaporating crucible as described above.

As could be seen, since the heat-conductive layer having higher thermal conductivity is provided on the inner wall of the crucible body, when the crucible body is heated with non-uniform temperatures, the heat-conductive layer can fast and evenly diffuse the heat, such that the entire heat-conductive layer may have uniform temperature and in turn the evaporation materials may be evenly heated. The heat-conductive structure connected to the heat-conductive layer may be further provided in the containing chamber, allowing the heat to be quickly transferred to the inside of the evaporation materials. As a result, various regions of the evaporation materials in the evaporating crucible may be evenly heated, thereby reducing the occurrence of denatured materials due to uneven temperature and then improving the effect of the evaporation.

### BRIEF DESCRIPTION OF THE DRAWINGS

Accompanying drawings are provided for further understanding of the present invention. These drawings constitute a part of the specification and are intended to explain the invention together with the following specific embodiments, but should not be considered as a limitation to the invention. In the drawings:

FIG. 1 is a structural schematic diagram of an existing evaporating crucible;

FIG. 2 a structural schematic diagram of an evaporating crucible according to a first embodiment of the invention;

FIG. 3 is a plan view of the evaporating crucible as shown in FIG. 2;

FIG. 4 a structural schematic diagram of an evaporating crucible according to a second embodiment of the invention; and

FIG. 5 is a plan view of the evaporating crucible as shown in FIG. 4.

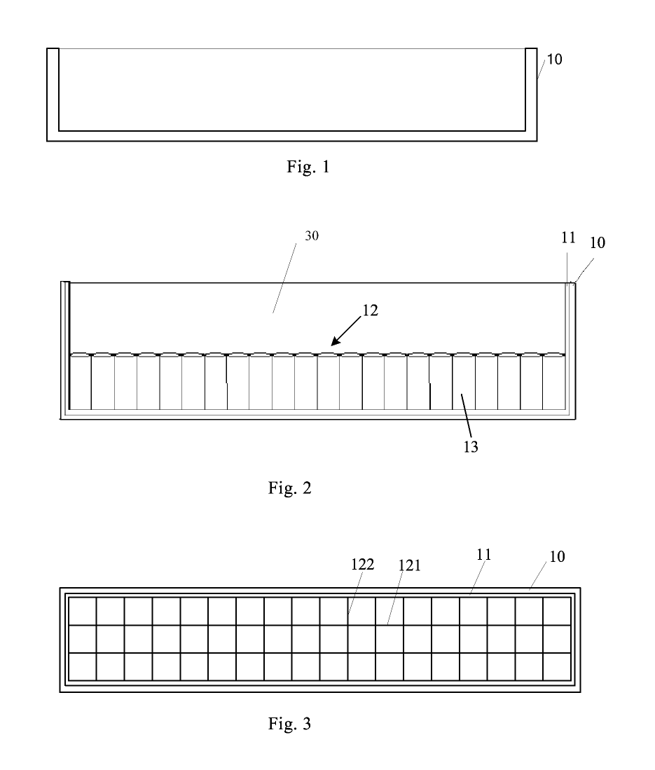

In reference numerals:

10—crucible body; 11—heat-conductive layer; 12—heat-conductive partition plate; 121—first partition plate; 122—second partition plate; 13—sub-chamber; 20—heat-conductive web; and 30—containing chamber

### DETAILED DESCRIPTION OF THE EMBODIMENTS

Hereafter, specific embodiments of the invention will be described in detail in conjunction with the drawings. It should be understood that the specific embodiments set forth herein is merely for the purpose of illustration and explanation of the invention and should not be constructed as limiting the invention.

As an aspect of the invention, there is provided an evaporating crucible. As shown in FIG. 2, the evaporating crucible according to the invention may include a crucible body 10 in which a containing chamber 30 is formed. The evaporating crucible according to the invention may further include a heat-conductive layer 11. The heat-conductive layer 11 is provided on an inner wall of the crucible body 10 to surround the containing chamber 30, and is made of materials having higher thermal conductivity than the crucible body 10.

The specific methods for applying the heat-conductive layer 11 to the inner wall of the crucible body 10 will not be restricted in the invention. For example, a plating method may be employed to applying materials with higher thermal conductivity directly to the inner wall of the crucible body 10 to form the heat-conductive layer 11; or a heat-conductive layer 11 having the same shape as the containing chamber may be pre-formed by using materials with higher thermal conductivity, and the pre-formed heat-conductive layer 11 may be then nested inside the containing chamber.

In the invention, when the evaporating crucible is being heated, since the heat-conductive layer 11 having higher thermal conductivity is provided on the inner wall of the crucible body 10, heat may be quickly transferred to the evaporation materials inside the containing chamber 30 through the heat-conductive layer 11. As a result, various regions of the evaporation materials in the evaporating crucible may be evenly heated, thereby reducing the occurrence of denatured materials due to uneven temperature and then improving the effect of the evaporation.

In particular, the crucible body 10 may have high temperature regions and low temperature regions after being heated. Since the crucible body 10 is provided with the heat-conductive layer 11 having higher thermal conductivity, the heat from the high temperature regions of the crucible body 10 may be more transferred to the heat-conductive layer 11. The heat-conductive layer 11 can fast diffuse the heat transferred from the high temperature regions, such that the entire heat-conductive layer 11 may have uniform temperature and in turn the evaporation materials may be evenly heated.

In the invention, the materials of which the crucible body 10 is made may include titanium or titanium alloy (for example, TC4), in such a manner that the evaporating crucible may have a greater heat resistance. The materials of which the heat-conductive layer 11 is made may include any one or more of copper, copper alloy, silver and silver alloy. As a matter of course, the materials of which the heat-conductive layer 11 is made may include other materials, as long as they have higher heat-conductivities and have no reaction with the evaporation materials.

In order to further improve the temperature uniformity of the evaporation materials, the evaporating crucible may further include heat-conductive structure which is arranged within the containing chamber 30 and connected to the heat-conductive layer 11. Preferably, when the evaporation materials are placed within the containing chamber 30, a portion of the evaporation materials may be brought into contact with the heat-conductive structure, and when the evaporating crucible is being heated, the evaporation materials may escape from the containing chamber 30. As it could be seen from above, the heat-conductive structure may not interfere with the escape of the evaporation materials from an open side of the containing chamber 30.

The specific forms of the heat-conductive structure will not be restricted in the invention, as long as the they may transfer the heat from the heat-conductive layer 11 to the inside of the evaporation materials and may not interfere with vaporization of the evaporation materials. For example, the heat-conductive structure may include a plurality of heat-conductive wires, heat-conductive rods or heat-conductive plates which are connected to the heat-conductive layer 11. When the evaporation materials are placed within the containing chamber 30, the heat-conductive structure may penetrate through the inside of the evaporation materials, so as to quickly transfer the heat to the inside of the evaporation materials. In the invention, the heat-conductive structure may be regarded as extensions of the heat-conductive layer, and the heat-conductive structure is provided for the purpose of increasing areas in contact with the evaporation materials, whereby more quickly and evenly heating the evaporation materials.

As an example of the heat-conductive structure, as shown in FIGS. 2 and 3, the heat-conductive structure may include a plurality of heat-conductive partition plates 12. The plurality of heat-conductive partition plates 12 may divide the containing chamber 30 into a plurality of sub-chambers 13 with openings formed, such that the evaporation materials placed within the plurality of sub-chambers 13 may escape from the openings. The heat-conductive partition plates 12 are connected to the heat-conductive layer 11, allowing the heat to be transferred to the inside of the plurality of sub-chambers 13. In this manner, the evaporation materials may be divided into a plurality of portions, such that the evaporation materials may have more uniform temperature. Preferably, the evaporation materials are uniformly distributed in each of sub-chambers 13.

In particular, as shown in FIG. 3, the plurality of the heat-conductive partition plates 12 may include at least a first partition plate 121 which is extended in a length direction of the containing chamber, and/or the plurality of the heat-conductive partition plates 12 may include at least a second partition plate 122 which is extended in a width direction of the containing chamber.

Preferably, as shown in FIG. 3, the plurality of the heat-conductive partition plates 12 may include a plurality of the first partition plates 121 and a plurality of the second partition plates 122. The plurality of the first partition plate 121 and the plurality of the second partition plate 122 may divide the containing chamber 30 into the plurality of sub-chambers 13. Openings are formed on the top of the sub-chambers 13, through which the evaporation materials being heated may escape.

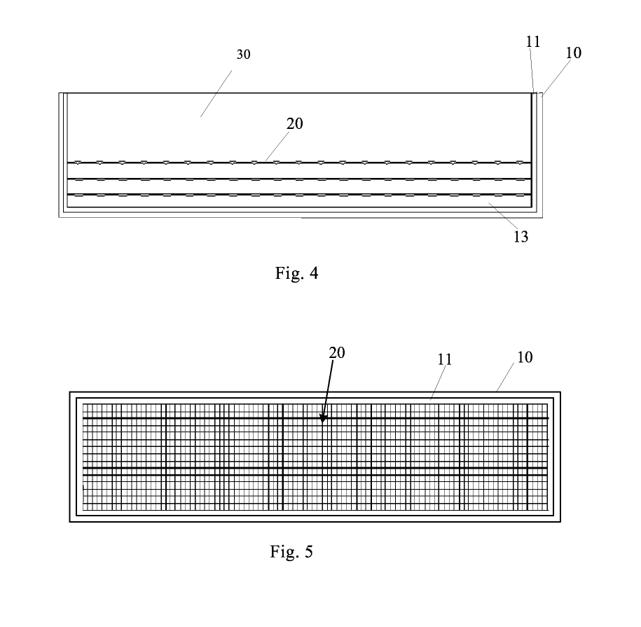

As another example of the heat-conductive structure, as shown in FIG. 4, the heat-conductive structure may include at least a heat-conductive web 20 which may divide the containing chamber 30 into a plurality of sub-chambers in a depth direction of the containing chamber. When one heat-conductive web 20 is provided, the heat-conductive web may divide the containing chamber 30 into upper and lower sub-chambers. FIG. 5 shows a plan view of the evaporating crucible in which the heat-conductive web 20 is provided. The evaporation materials may escape from meshes of the heat-conductive web 20. It should be understood that the heat-conductive web 20 is preferably arranged at a lower portion of the containing chamber 30, such that the evaporation materials in the containing chamber may cover the heat-conductive web 20 (in other words, the heat-conductive web 20 is positioned inside the evaporation materials), allowing the heat of the heat-conductive web 20 to be transferred to the inside of the evaporation materials. In this manner, the heat-conductive layer 11 and the heat-conductive web 20 may heat the evaporation materials from both inside and outside, such that the evaporation materials may have uniform temperature. Unless otherwise specified, terms such as “upper”, “lower”, “upper potion” and “lower portion” used in the embodiment all refer to upward and downward directions in FIG. 4.

Preferably, as shown in FIG. 4, the heat-conductive structure may include a plurality of heat-conductive webs 20 which are arranged in the depth direction of the containing chamber 30. The plurality of heat-conductive webs 20 may be arranged at an equal interval or in other manners. In should be understood that the evaporation materials within the containing chamber 30 at least cover at least one heat-conductive web 20. When the evaporating crucible is being heated, the plurality of heat-conductive webs 20 may uniformly transfer the heat to the inside of the evaporation materials. In the case of a great amount of the evaporation materials, the plurality of heat-conductive webs 20 may improve the temperature uniformity of the evaporation materials and enhance the effect of evaporation.

Preferably, the heat-conductive structure may be made of the same materials as the heat-conductive layer 11, and particularly both of them are made of the materials having higher thermal conductivity, so as to quickly transfer the heat to the inside of the evaporation materials and in turn to improve the temperature uniformity. In particular, the materials of which the heat-conductive structure is made may include any one or more of copper, copper alloy, silver and silver alloy.

The evaporating crucible according to the invention has been described above. As could be seen, since the heat-conductive layer having higher thermal conductivity is provided on the inner wall of the crucible body, when the crucible body is heated with non-uniform temperatures, the heat-conductive layer can fast and evenly diffuse the heat, such that the entire heat-conductive layer may have uniform temperature and in turn the evaporation materials may be evenly heated. The heat-conductive structure connected to the heat-conductive layer may be further provided in the containing chamber, allowing the heat to be quickly transferred to the inside of the evaporation materials. As a result, various regions of the evaporation materials in the evaporating crucible may be evenly heated, thereby reducing the occurrence of denatured materials due to uneven temperature and then improving the effect of the evaporation.

As another aspect of the invention, there is provided an evaporating device. The evaporating device includes above evaporating crucible according to the invention. The evaporating device may include a vacuum chamber in which the evaporating crucible is arranged. Since the evaporating device is provided with the evaporating crucible as described above, the evaporating device according to the invention may also realize a better effect of the evaporation.

It should be understood that the above embodiments are merely exemplary embodiments for the purpose of illustrating the principle of the invention, and the invention is not limited thereto. Various modifications and improvements can be made by a person having ordinary skill in the art without departing from the spirit and the essence of the invention. Accordingly, all of the modifications and improvements also fall into the protection scope of the invention.

1-10 (canceled)

11. An evaporating crucible, including a crucible body in which a containing chamber is formed, wherein
the evaporating crucible further includes a heat-conductive layer which is provided on an inner wall of the crucible body to surround the containing chamber and which is made of materials having higher thermal conductivity than the crucible body.

12. The evaporating crucible according to claim 11, wherein
the materials of which the crucible body is made include titanium or titanium alloy, and the materials of which the heat-conductive layer is made include any one or more of copper, copper alloy, silver and silver alloy.

13. The evaporating crucible according to claim 11, wherein
the evaporating crucible further includes a heat-conductive structure which is arranged within the containing chamber and connected to the heat-conductive layer, and
when the evaporation materials are placed within the containing chamber, the evaporation materials are brought into contact with at least a portion of the heat-conductive structure, and when the evaporating crucible is being heated, the heat-conductive structure has no interference with the escape of the evaporation materials from an open side of the containing chamber.

14. The evaporating crucible according to claim 12, wherein
the evaporating crucible further includes a heat-conductive structure which is arranged within the containing chamber and connected to the heat-conductive layer, and
when the evaporation materials are placed within the containing chamber, the evaporation materials are brought into contact with at least a portion of the heat-conductive structure, and when the evaporating crucible is being heated, the heat-conductive structure has no interference with the escape of the evaporation materials from an open side of the containing chamber.

15. The evaporating crucible according to claim 13, wherein
the heat-conductive structure includes a plurality of heat-conductive partition plates which divide the containing chamber into a plurality of sub-chambers with openings formed.

16. The evaporating crucible according to claim 15, wherein
the plurality of the heat-conductive partition plates include at least a first partition plate which is extended in a length direction of the containing chamber, and/or
the plurality of the heat-conductive partition plates include at least a second partition plate which is extended in a width direction of the containing chamber.

17. The evaporating crucible according to claim 16, wherein
the plurality of the heat-conductive partition plates include a plurality of the first partition plates and a plurality of the second partition plates.

18. The evaporating crucible according to claim 13, wherein
the heat-conductive structure includes at least a heat-conductive web which divides the containing chamber into a plurality of sub-chambers in a depth direction of the containing chamber.

19. The evaporating crucible according to claim 18, wherein
the heat-conductive structure includes a plurality of heat-conductive webs which are arranged in the depth direction of the containing chamber.

20. The evaporating crucible according to claim 13, wherein
the heat-conductive structure is made of the same materials as the heat-conductive layer.

21. An evaporating device, wherein the evaporating device includes the evaporating crucible according to claim 11.

22. The evaporating device according to claim 21, wherein
the materials of which the crucible body is made include titanium or titanium alloy, and the materials of which the heat-conductive layer is made include any one or more of copper, copper alloy, silver and silver alloy.

23. The evaporating device according to claim 21, wherein
the evaporating crucible further includes a heat-conductive structure which is arranged within the containing chamber and connected to the heat-conductive layer, and
when the evaporation materials are placed within the containing chamber, the evaporation materials are brought into contact with at least a portion of the heat-conductive structure, and when the evaporating crucible is being heated, the heat-conductive structure has no interference with the escape of the evaporation materials from an open side of the containing chamber.

24. The evaporating device according to claim 22, wherein
the evaporating crucible further includes a heat-conductive structure which is arranged within the containing chamber and connected to the heat-conductive layer, and
when the evaporation materials are placed within the containing chamber, the evaporation materials are brought into contact with at least a portion of the heat-conductive structure, and when the evaporating crucible is being heated, the heat-conductive structure has no interference with the escape of the evaporation materials from an open side of the containing chamber.

25. The evaporating device according to claim 23, wherein
the heat-conductive structure includes a plurality of heat-conductive partition plates which divide the containing chamber into a plurality of sub-chambers with openings formed.

26. The evaporating device according to claim 25, wherein
the plurality of the heat-conductive partition plates include at least a first partition plate which is extended in a length direction of the containing chamber, and/or
the plurality of the heat-conductive partition plates include at least a second partition plate which is extended in a width direction of the containing chamber.

27. The evaporating device according to claim 26, wherein
the plurality of the heat-conductive partition plates include a plurality of the first partition plates and a plurality of the second partition plates.

28. The evaporating device according to claim 23, wherein
the heat-conductive structure includes at least a heat-conductive web which divides the containing chamber into a plurality of sub-chambers in a depth direction of the containing chamber.

29. The evaporating device according to claim 28, wherein
the heat-conductive structure includes a plurality of heat-conductive webs which are arranged in the depth direction of the containing chamber.

30. The evaporating device according to claim 23, wherein
the heat-conductive structure is made of the same materials as the heat-conductive layer.
